(19) United States
(12) Patent Application Publication
(10) Pub. No.: US 2023/0340688 A1
(43) Pub. Date: Oct. 26, 2023

(54) PLATING APPARATUS

(71) Applicant: EBARA CORPORATION, Tokyo (JP)

(72) Inventors: Tsubasa ISHII, Tokyo (JP); Masashi SHIMOYAMA, Tokyo (JP); Masashi OBUCHI, Tokyo (JP); Koichi MASUYA, Tokyo (JP); Ryosuke HIWATASHI, Tokyo (JP)

(21) Appl. No.: 18/168,486

(22) Filed: Feb. 13, 2023

(30) Foreign Application Priority Data
Apr. 22, 2022 (JP) 2022-070681

(51) Int. Cl. C25D 21/12; C25D 17/02; C25D 17/06; C25D 17/10

(52) U.S. Cl. CPC C25D 21/12; C25D 17/02; C25D 17/06; C25D 17/10

(57) ABSTRACT

An object is to precisely grasping, in real time, film thickness of a plated film during a plating process. A plating apparatus comprises: a plating tank for storing plating liquid; a substrate holder for holding a substrate; an anode arranged in the plating tank in such a manner that it faces the substrate held by the substrate holder; an electric potential sensor constructed in such a manner that it is arranged in a position close to the substrate held by the substrate holder, and measures electric potential of the plating liquid; and a state space model constructed to estimate current density of current flowing through an outer edge part of the substrate, based on a measured value of electric potential of the plating liquid obtained by the electric potential sensor and by using a state equation and an observation equation.

### CROSS REFERENCE TO RELATED APPLICATION

This application claims priority to Japanese Patent Application No. 2022-070681 filed Apr. 22, 2022, the entire contents of which are hereby incorporated by reference.

### TECHNICAL FIELD

The present invention relates to a technique for measuring thickness of a plated film in a plating apparatus.

### BACKGROUND ART

A method for calculating a film thickness of an object of electrolytic treatment, wherein a magnetic sensor is arranged in a position adjacent to the object, distribution of magnetic flux density during the electrolytic treatment is measured by the magnetic sensor, surface current density of the object is obtained based on the distribution of the magnetic flux density, and the film thickness of the object is calculated based on the surface current density, has been known (for example, refer to Patent Literature 1).

### CITATION LIST

### Patent Literature

PTL 1: Japanese Patent Application Public Disclosure No. 2008-014699

### SUMMARY OF INVENTION

### Technical Problem

It is desired to grasp plated film thickness accurately in real time during a plating process.

### Solution to Problem

(Mode 1) According to Mode 1, a plating apparatus is provided, wherein the plating apparatus comprises: a plating tank for storing plating liquid; a substrate holder for holding a substrate; an anode arranged in the plating tank in such a manner that it faces the substrate held by the substrate holder; an electric potential sensor constructed in such a manner that it is arranged in a position close to the substrate held by the substrate holder, and measures electric potential of the plating liquid; and a state space model constructed to estimate current density of current flowing through an outer edge part of the substrate, based on a measured value of electric potential of the plating liquid obtained by the electric potential sensor and by using a state equation and an observation equation.

(Mode 2) According to Mode 2, the Mode 2 comprises the plating apparatus of Mode 1, wherein the state equation of the state space model describes time evolution relating to the current density of the current flowing through the outer edge part of the substrate.

(Mode 3) According to Mode 3, the Mode 3 comprises the plating apparatus of Mode 2, wherein the observation equation of the state space model describes relationship between the current density of the current flowing through the outer edge part of the substrate and potential of the plating liquid in a position of the electric potential sensor.

(Mode 4) According to Mode 4, the Mode 4 comprises the plating apparatus of Mode 3 and comprises a plating module comprising at least the plating tank, the substrate holder, the anode, and the electric potential sensor, and the relationship between the current density and the potential of the plating liquid is that based on a function representing a 3D model of the plating module.

(Mode 5) According to Mode 5, the Mode 5 comprises the plating apparatus of Mode 1, wherein the state space model further comprises a Kalman filter constructed to correct, based on the measured value obtained by the electric potential sensor, result of estimation of the current density of the current flowing through the outer edge part of the substrate.

(Mode 6) According to Mode 6, the Mode 6 comprises the plating apparatus of Mode 1 and further comprises a current density calculator constructed to calculate, based on the current density estimated by the state space model, plating current density of plating current flowing into the substrate from the plating liquid.

(Mode 7) According to Mode 7, the Mode 7 comprises the plating apparatus of Mode 6 and further comprises a film thickness calculator constructed to calculate, based on the plating current density calculated by the current density calculator, film thickness of a plated film formed on the substrate.

(Mode 8) According to Mode 8, the Mode 8 comprises the plating apparatus of Mode 6, wherein the outer edge part of the substrate is a part, which is grasped by the substrate holder, of the substrate.

(Mode 9) According to Mode 9, the Mode 9 comprises the plating apparatus of Mode 8, wherein the plating current density calculated by the current density calculator is current density in a region positioned on the inward side of the outer edge part in the substrate.

### BRIEF DESCRIPTION OF DRAWINGS

FIG. 1 is a perspective view of an entire construction of a plating apparatus according to a present embodiment.

FIG. 2 is a top view of the entire construction of the plating apparatus according to the present embodiment.

FIG. 3 is a longitudinal section view which schematically shows a construction of a plating module in an embodiment.

FIG. 4 is a schematic diagram which shows, in an enlarged manner, a periphery of a pipe in the plating module.

FIG. 5 is a block diagram which shows a functional construction of a control module in the plating apparatus in the present embodiment.

FIG. 6 is a top view of a substrate.

FIG. 7 is a longitudinal section view which schematically shows a construction of a plating module in a different embodiment.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

### First Embodiment

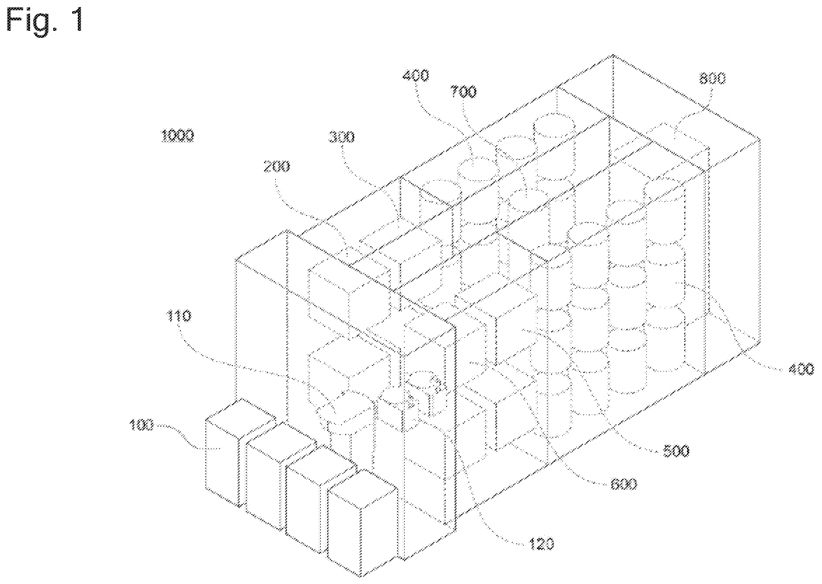

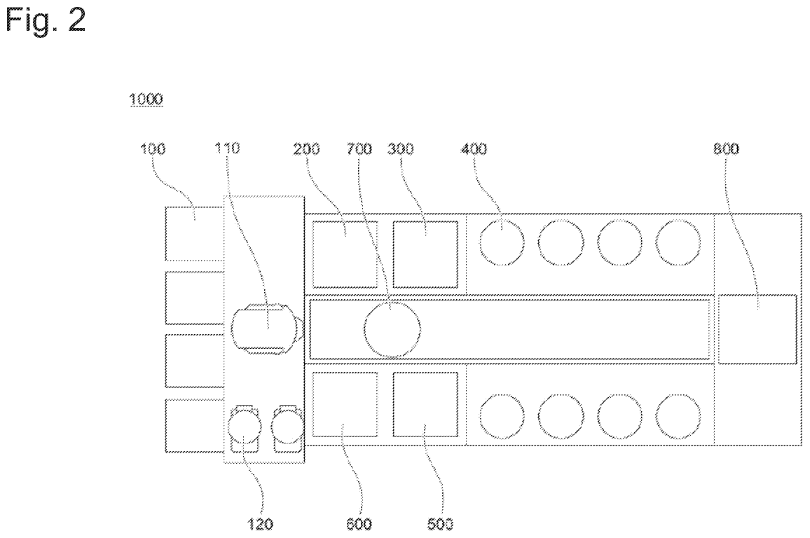

FIG. 1 is a perspective view of an entire construction of a plating apparatus according to a present embodiment. FIG. 2 is a top view of the entire construction of the plating apparatus according to the present embodiment. As shown in FIGS. 1 and 2, a plating apparatus 1000 comprises a load port 100, a transfer robot 110, an aligner 120, a pre-wet module 200, a pre-soak module 300, a plating module 400, a washing module 500, a spin rinse dryer 600, a transfer device 700, and a control module 800.

The load port 100 is a module for carrying a substrate, which is housed in a cassette such as a FOUP which is not shown in the figure, in the plating apparatus 1000, and carrying a substrate out of the plating apparatus 1000 and housing it in a cassette. In the present embodiment, four load ports 100 are arranged side by side in a horizontal direction; however, the number of the load ports 100 and arrangement thereof are matters that can be determined optionally. The transfer robot 110 is a robot for conveying a substrate, and is constructed to deliver a substrate between the load port 100, the aligner 120, and the transfer device 700. Regarding the transfer robot 110 and the transfer device 700, when a substrate is delivered between the transfer robot 110 and the transfer device 700, delivering of the substrate can be performed via a temporary holding table which is not shown in the figure.

The aligner 120 is a module for aligning, in a predetermined direction, a position of an orientation flat, a notch, or the like of a substrate. In the present embodiment, two aligners 120 are arranged side by side in a horizontal direction; however, the number of the aligners 120 and arrangement thereof are matters that can be determined optionally. The pre-wet module 200 makes a to-be-plated surface of a substrate, which is in a state before application of a plating process, wet by applying a treatment liquid such as pure water, degassed water, or the like thereto, to thereby replace air existing in the inside of a pattern formed on the surface of the substrate by the treatment liquid. The pre-wet module 200 is constructed to perform a pre-wet process that facilitates supplying of a plating liquid to the inside of the pattern during a plating process, by allowing the treatment liquid in the inside of the pattern to be replaced by the plating liquid. In the present embodiment, two pre-wet modules 200 are arranged side by side in a vertical direction; however, the number of the pre-wet modules 200 and arrangement thereof are matters that can be determined optionally.

The pre-soak module 300 is constructed to perform a pre-soak process for washing or activating a surface of a ground to which a plating process is to be applied, for example, by removing an oxide film which has large electric resistance and exists on a surface of a seed layer or the like formed on a to-be-plated surface of a substrate which is in a state before application of a plating process, by applying an etching process using a treatment liquid such as sulfuric acid, hydrochloric acid, or the like. In the present embodiment, two pre-soak modules 300 are arranged side by side in a vertical direction; however, the number of the pre-soak modules 200 and arrangement thereof are matters that can be determined optionally. The plating modules 400 applies a plating process to a substrate. In the present embodiment, two sets of plating modules 400 are included; wherein each set includes 12 plating modules 400 which are arranged in such a manner that three plating modules 400 are arranged side by side in a vertical direction and four plating modules 400 are arranged side by side in a horizontal direction, so that a total of 24 plating modules 400 are installed; however, the number of the plating modules 400 and arrangement thereof are matters that can be determined optionally.

The washing module 500 is constructed to perform a washing process applied to a substrate for removing a plating liquid and so on remaining on a substrate which is in a state after completion of the plating process. In the present embodiment, two washing modules 500 are arranged side by side in a vertical direction; however, the number of the washing modules 500 and arrangement thereof are matters that can be determined optionally. The spin rinse dryer 600 is a module for drying a substrate, which is in a state after completion of the washing process, by rotating it at high speed.

In the present embodiment, two spin rinse dryers are arranged side by side in a vertical direction; however, the number of the spin rinse dryers and arrangement thereof are matters that can be determined optionally. The transfer device 700 is a device for conveying a substrate between plural modules in the plating apparatus 1000. The control module 800 is constructed to control plural modules in the plating apparatus 1000, and may be constructed by using, for example, a general-purpose computer or a special-purpose computer comprising an input/output interface for communication with an operator.

An example of a series of processes of plating by the plating apparatus 1000 will be explained. First, a substrate housed in a cassette is carried in the load port 100. Next, the transfer robot 110 takes the substrate out of the cassette in the load port 100, and conveys the substrate to the aligner 120. The aligner 120 aligns, in a predetermined direction, a position of an orientation flat, a notch, or the like of the substrate. The transfer robot 110 conveys the substrate, which has been aligned with respect to the direction by the aligner 120, to the transfer device 700.

The transfer device 700 conveys the substrate received from the transfer robot 110 to the pre-wet module 200. The pre-wet module 200 applies a pre-wet process to the substrate. The transfer device 700 conveys the substrate, to which the pre-wet process has been applied, to the pre-soak module 300. The pre-soak module 300 applies a pre-soak process to the substrate. The transfer device 700 conveys the substrate, to which the pre-soak process has been applied, to the plating module 400. The plating module 400 apples a plating process to the substrate.

The transfer device 700 conveys the substrate, to which the plating process has been applied, to the washing module 500. The washing module 500 applies a washing process to the substrate. The transfer device 700 conveys the substrate, to which the washing process has been applied, to the spin rinse dryer 600. The spin rinse dryer 600 applies a drying process to the substrate. The transfer device 700 conveys the substrate, to which the drying process has been applied, to the transfer robot 110. The transfer robot 110 conveys the substrate received from the transfer device 700 to the cassette in the load port 100. Finally, the cassette, in which the substrate has been housed, is carried out of the load port 100.

In this regard, the construction of the plating apparatus 1000 explained in relation to FIGS. 1 and 2 is not that limited to each of the constructions shown in FIGS. 1 and 2.

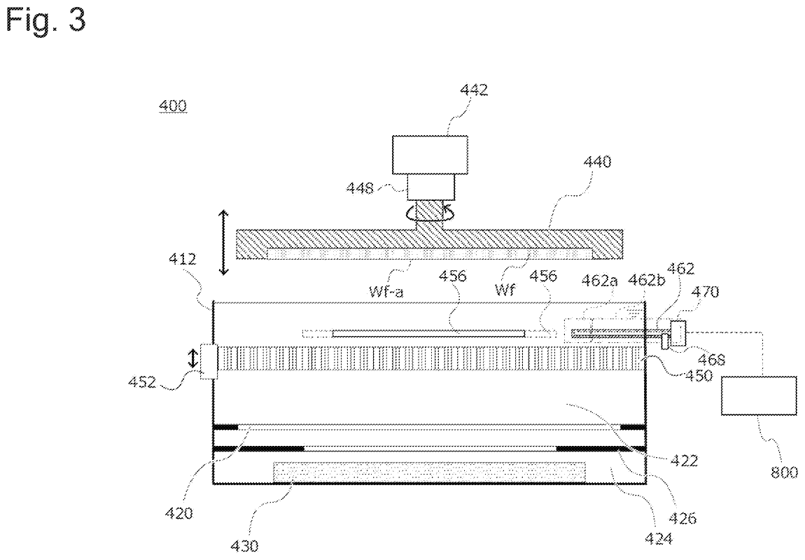

Next, a construction of the plating module 400 will be explained. Since respective constructions of the 24 plating modules 400 in the present embodiment are identical with one another, explanation with respect to a single plating module 400 will be provided herein. FIG. 3 is a longitudinal section view which schematically shows a construction of the plating module 400 in a first embodiment. The plating module 400 comprises a plating tank for storing plating liquid. The plating tank is constructed in such a manner that it comprises an inner tank 412 which has a cylindrical shape having an opened upper surface, and an outer tank which is not shown in the figure, wherein the outer tank is installed around the inner tank 412 for storing the plating liquid that has overflowed the upper edge of the inner tank 412.

The plating module 400 comprises a substrate holder 440 for holding a substrate Wf in a state that a to-be-plated surface Wf-a faces downward. Further, the substrate holder 440 comprises an electric power supplying contact for supplying electric power to the substrate Wf from an electric power source which is not shown in the figure. The plating module 400 comprises an ascending/descending mechanism 442 for moving up/down the substrate holder 440. Further, in an embodiment, the plating module 400 comprises a rotation mechanism 448 for rotating the substrate holder 440 about a vertical axis. The ascending/descending mechanism 442 and the rotation mechanism 448 can be realized by using publicly known mechanisms such as a motor and so on, for example.

The plating module 400 comprises a membrane 420 which separates, in a vertical direction, the inside of the inner tank 412. The inside of the inner tank 412 is partitioned into a cathode region 422 and an anode region 424 by the membrane 420. Each of the cathode region 422 and the anode region 424 is filled with plating liquid. In this regard, the membrane 420 may not be installed, although an example in which the membrane 420 is installed is explained herein in relation to the present embodiment.

An anode 430 is installed on a bottom surface of the inner tank 412 in the anode region 424. Further, an anode mask 426 is arranged in the anode region 424, for adjusting an electric field between the anode 430 and the substrate Wf. The anode mask 426 is a member which has an approximately plate shape and comprises dielectric material, for example, and is arranged in a position in front of a front surface of the anode 430 (or a position above the anode 430 in FIG. 3). The anode mask 426 has an opening, and current flowing between the anode 430 and the substrate Wf passes through the opening. The anode mask 426 is constructed in such a manner that the size of the opening thereof is changeable, and the size of the opening may be adjusted by the control module 800. The size of the opening refers to the diameter in the case that the opening has a circular shape, or the length of a side or the longest opening width in the case that the opening has a polygonal shape. Changing of the size of the opening of the anode mask 426 may be realized by adopting a publicly known mechanism. In this regard, the anode mask 426 may not be installed, although an example in which the anode mask 426 is installed is explained herein in relation to the present embodiment. Further, the above-explained membrane 420 may be installed in the opening of the anode mask 426.

A resistive element 450 is arranged in the cathode region 422 in such a manner that it faces the membrane 420. The resistive element 450 is a member used for the purpose of uniform application of the plating process on the to-be-plated surface Wf-a of the substrate Wf. In an embodiment, the resistive element 450 is constructed in such a manner that it can be moved upward and downward within the plating tank by a driving mechanism 452, and the position of the resistive element 450 is adjusted by the control module 800. In this regard, the plating module 400 may not have the resistive element 450. A tangible material of the resistive element 450 is not specifically limited; however, for example, porous resin such as polyetheretherketone or the like may be used as a material thereof.

A paddle 456 for stirring the plating liquid is arranged in a position close to the surface of the substrate Wf in the cathode region 422. The paddle 456 is constructed by using titanium (Ti) or resin, for example. The paddle 456 stirs the plating liquid by performing reciprocating movement in a direction parallel to the surface of the substrate Wf, to thereby supply sufficient quantity of metal ions uniformly to the surface of the substrate Wf during plating of the substrate Wf. It should be reminded that the construction is not limited to that explained above, and the paddle 456 may be constructed to move in a direction perpendicular to the surface of the substrate Wf. Also, in this regard, the plating module 400 may not comprise the paddle 456.

Further, a pipe 462 is installed in the cathode region 422. The pipe 462 is a hollow tube, and may be formed by using, for example, resign such as PP (polypropylene), PVC (polyvinyl chloride), or the like. In this regard, in the case that the cathode region 422 is provided with the resistive element 450, the tube 462 may be arranged in a position between the substrate Wf and the resistive element 450. Further, in the case that the paddle 456 is installed, the tube 462 may be arranged in such a manner that it does not interfere with the paddle 456; for example, it is preferable that the tube 462 be arranged in a position that is level with the paddle 456 and on the side of an outer periphery of the paddle 456 (the outer sides in the left and right directions in FIG. 3).

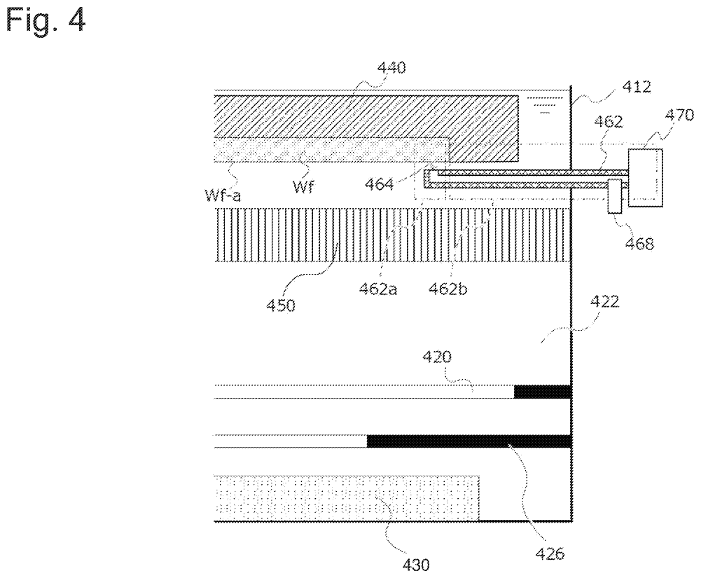

FIG. 4 is a schematic diagram which shows, in an enlarged manner, a periphery of the pipe 462 in the plating module 400. As shown in FIGS. 3 and 4, the pipe 462 comprises an open end 464 positioned in a region between the substrate Wf and the anode 430. That is, the open end 464 is formed in a position in a direction perpendicular to the plate surface of the substrate Wf and between the substrate Wf and the anode 430, so that it is formed in a position that overlaps the substrate Wf when it is viewed from the direction perpendicular to the plate surface of the substrate Wf. It is preferable to adopt the construction wherein the open end 464 is positioned close to the to-be-plated surface Wf-a and formed to face the to-be-plated surface Wf-a. For example, the distance between the open end 464 and the to-be-plated surface Wf-a may be that in a range between several hundred micrometers and dozens of millimeters. It should be reminded that the open end 464 may be opened in a direction perpendicular to a direction from the substrate Wf to the anode 430 or vice versa (the left and right directions in FIGS. 3 and 4), or may be opened in a slanted direction toward the to-be-plated surface Wf-a of the substrate Wf. Further, the pipe 462 extends to a region distant from the region between the substrate Wf and the anode 430. Thus, the pipe 462 comprises a first part 462a positioned in the region between the substrate Wf and the anode 430 and a second part 462b positioned in the region distant from the region between the substrate Wf and the anode 430. It is preferable that the pipe 462 be extended in a direction (the left/right direction in each of FIGS. 3 and 4)) that is perpendicular to the direction (the upward/downward direction in each of FIGS. 3 and 4) from the substrate Wf to the anode 430 or vice versa. In an embodiment, the pipe 462 extends to the outside of the plating tank. In this regard, the construction is not limited to that of this example, and the pipe 462 may extend to any optional direction.

The inside of the pipe 462 is filled with the plating liquid in a manner similar to that relating to the cathode region 422. The pipe 462 may be provided with a filling mechanism 468 for filling the inside thereof with the plating liquid. A mechanism in publicly known various mechanisms can be adopted as the filling mechanism 468; and, for example, a purge valve, a mechanism for supplying plating liquid, or the like may be adopted as the filling mechanism 468. For example, the filling mechanism 468 is installed in the second part 462b of the pipe 462.

It should be reminded that, although a single pipe 462 is shown in each of FIGS. 3 and 4 for simplicity, plural pipes 462 may be installed in the plating tank. In the case that plural pipes 462 are installed, the open ends 462 of the pipes 462 may be arranged in positions at different distances from the center of the substrate Wf, respectively. Further, in the case that plural pipes 462 are installed, it is preferable that the open ends 462 of the pipes 462 be arranged in positions at same distances from the to-be-plated surface Wf-a of the substrate Wf, respectively.

The second part 462b of the pipe 462 is provided with an electric potential sensor 470. In this regard, although the electric potential sensor 470 is arranged in a position in the outside of the plating tank in each of FIGS. 3 and 4, it may be arranged in a position in the inside of the plating tank. The electric potential sensor 470 measures electric potential of the plating liquid in the pipe 462. In this regard, the plating liquid in the pipe 462 has electric potential that is approximately the same as that of the plating liquid around the open end 464, so that the electric potential detected by the electric potential sensor 470 is approximately the same as that of the plating liquid around the open end 464. Thus, the region close to the open end 464 can be regarded as a pseudo electric potential detecting position for the electric potential sensor 470. Accordingly, electric potential in a region close to the to-be-plated surface Wf-a can be measured by using the electric potential sensor 470 installed in the second part 462b of the pipe 462. The detection signal from the electric potential sensor 470 is inputted to the control module 800.

In an embodiment, a reference electric potential sensor (which is not shown in the figure) may be installed in a position, where change in electric potential is relatively small, in the plating tank; and it is preferable that a difference between the electric potential detected by the reference electric potential sensor and the electric potential detected by the electric potential sensor 470 be obtained. Since change in the electric potential measured by the electric potential sensor 470 is very small, the measured electric potential is subject to noise. For reducing noise, it is preferable to arrange an independent electrode in the plating liquid, and directly connect the electrode to ground.

The control module 800 can estimate, based on the value of the electric potential detected by the electric potential sensor 470, film thickness of the plated film formed on the substrate Wf. For example, the control module 800 can estimate, based on a detection signal from the electric potential sensor 470, distribution of plating current in the substrate surface during the plating process, and can estimate, based on the estimated distribution of the plating current, distribution of film thickness of the plated film on the substrate.

Further, based on the detection value obtained from the electric potential sensor 470, the control module 800 may perform operation for detecting an end point of the plating process, and/or estimate time required to reach the end point of the plating process. For example, the control module 800 may terminate the plating process when the film thickness of the plated film, that is estimated based on the detection value obtained from the electric potential sensor 470, has reached a desired thickness. Further, in an example, the control module 800 may calculate a film thickness increasing rate from the film thickness of the plated film, that is estimated based on the detection value obtained from the electric potential sensor 470, and estimate, based on the obtained film thickness increasing rate, time required for increasing the film thickness until the desired thickness, that is, time required to reach the end point of the plating process.

The plating process in the plating module 400 will be explained hereinafter. The substrate Wf is exposed to the plating liquid, by soaking the substrate Wf in the plating liquid in the cathode region 422 by using the ascending/descending mechanism 442. While maintaining the above state, the plating module 400 applies the plating process to the to-be-plated surface Wf-a of the substrate Wf, by applying a voltage between the anode 430 and the substrate Wf. Further, in an embodiment, the substrate holder 440 is rotated by using the rotation mechanism 448 when the plating process is being performed. As a result of extraction by the plating process, a conductive film (a plated film) is formed on the to-be-plated surface Wf-a of the substrate Wf. During the plating process, measurement of electric potential by the electric potential sensor 470, which has been installed in the pipe 462, is performed. By performing measurement by the electric potential sensor 470 while the substrate holder 440 (the substrate Wf) is being rotated, it becomes possible to change the position of measurement by the electric potential sensor 470, and measure electric potential of plural points in a circumferential direction of the substrate Wf or the whole part in the circumferential direction. Thereafter, the control module 800 estimates, based on the value of the electric potential detected by the electric potential sensor 470, the film thickness of the plated film. As a result, it becomes possible to grasp, in real time during the plating process, change in the film thickness of the plated film formed on the to-be-plated surface Wf-a of the substrate Wf.

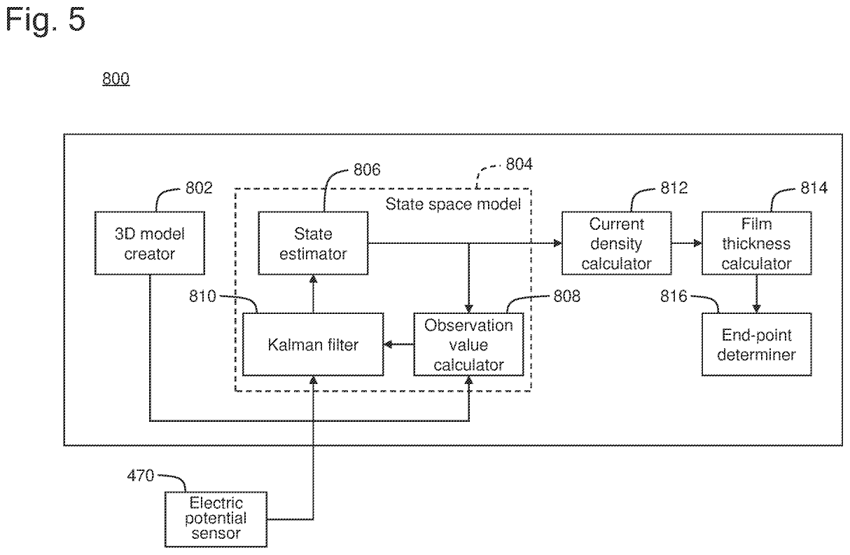

FIG. 5 is a block diagram which shows a functional construction of the control module 800 in the plating apparatus 1000 in the present embodiment. The control module 800 is constructed to estimate, by using a state space model 804, distribution of density of current flowing through the substrate Wf during the plating process. The state space model 804 comprises a state estimator 806, an observation value calculator 808, and a Kalman filter 810. The control module 800 comprises, in addition to the state space model 804, a 3D model creator 802, a current density calculator 812, a film thickness calculator 814, and an end-point determiner 816. The control module 800 may be constructed as a computer comprising an input/output device, an arithmetic and logic unit, a storage device, and so on. For example, the control module 800 is constructed to realize functions of the respective units 802, 806, 808, 810, 812, 814, and 816 by reading and executing, by an arithmetic and logic unit (for example a processor), computer programs stored in a storage device.

The 3D model creator 802 creates a three dimensional (3D) model of the plating module 400. The 3D model of the plating module 400 is data constructed by modelling shapes, positions, physical properties, and so on in the plating module and describing them. At least, components affecting the electric field in the inside of the plating tank (the inner tank 412) of the plating module 400 are incorporated in the 3D model. Such components includes, for example, the anode 430, the anode mask 426, the membrane 420, the resistive element 450, the substrate Wf, the seed layer formed on the substrate Wf, the plating liquid held in the plating tank, the pipe 462, and the electric potential sensor 470. The 3D model of the plating module 400 may be constructed by using information of shapes, positions, and physical properties (for example, conductivity, dielectric constants, and so on) relating to the above respective components. For example, the above information may be inputted to the control module 800 via an input/output interface of the control module 800 by an operator of the plating apparatus 1000, and the 3D model creator 802 may create the 3D model of the plating module 400 based on the inputted information. Part of the above information, for example, some physical properties, may be stored in the storage device of the control module 800 in advance, and an operator may select an appropriate value from the stored physical properties.

The state estimator 806 is constructed to estimate a “state” of the plating module 400 by using a state equation. Specifically, the state estimator 806 estimates, as a “state” of the plating module 400, current density of plating current in the outer edge part of the substrate Wf.

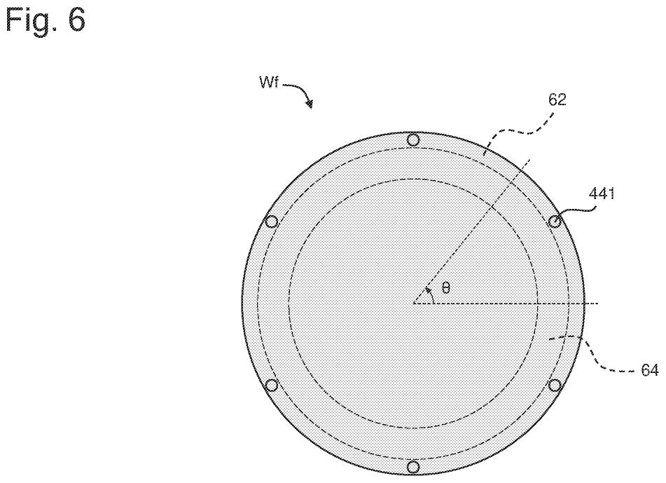

FIG. 6 is a top view of the substrate Wf. An outer edge part 62 of the substrate Wf is a part which is grasped when grasping the substrate Wf by the substrate holder 440, and is not exposed to the plating liquid. As shown in FIG. 6, the substrate Wf comprises one or plural electric contacts 441 in the outer edge part 62. In the example shown in FIG. 6, the outer edge part 62 comprises evenly spaced six electric contacts 441 in the outer edge part 62. Each of the electric contacts 441 is connected to a negative terminal of an electric power source (which is not shown in the figure) via an electric wire (which is not shown in the figure) which has been built in the substrate holder 440, and the plating current flows to the substrate Wf through the electric contact 441.

In the following description, the current density of the plating current in the outer edge part 62 of the substrate Wf will be referred to as “outer-edge-part current density,” and the outer-edge-part current density at time t will be described as jt(θ). In this regard, θ represents a position in the outer edge part 62 of the substrate Wf, that is measured in terms of an angle about the center of the substrate Wf (refer to FIG. 6). In the present case, the outer-edge-part current density jt(θ) is represented by the Fourier series shown below.

(Formula 1)

Estimation of the outer-edge-part current density jt(θ) comes down to estimation of Fourier coefficients ai,t and bi,t. In an embodiment, the state estimator 806 estimates (forecasts), from outer-edge-part current density jt(θ) at time t−1, outer-edge-part current density jt(θ) at time t by using the following state equation.

(Formula 2)

In this regard, the matrix Fi is given by the formula shown below, and represents rotation of the substrate Wf using the rotation mechanism 448. In addition, the vector vt represents noise. In the present model, it is assumed that the outer-edge-part current density at time t is given by rotating, along rotation of the substrate Wf, the outer-edge-part current density at time t−1. In the following formula, ω is angular velocity of rotation of the substrate Wf, and Δt is a time step (that is, difference in time between time t and time t−1).

(Formula 3)

In this regard, a state equation different from the above formula may be used for estimating the outer-edge-part current density.

The observation value calculator 808 is constructed to estimate an “observation value” from a “state” of the plating module 400 by using an observation equation. Specifically, the observation value calculator 808 estimates (calculates), from the outer-edge-part current density jt(θ), a value of electric potential of the plating liquid in the plating tank, that is expected to be measured by the electric potential sensor 470, as an “observation value” in the plating module 400. In the following description, the value calculated by the observation value calculator 808 will be referred to as an “electric potential estimated value,” and an electric potential estimated value at time t will be described as (pt.

As explained above, the electric potential measured by the electric potential sensor 470 is electric potential in a region close to the to-be-plated surface Wf-a of the substrate Wf to which the plating process is being applied. The above electric potential is determined based on distribution of plating current flowing to the substrate Wf from the plating liquid in the plating tank. Further, the distribution of the plating current is dependent on the physical structure of the plating module 400. Thus, the electric potential estimated value φt can be calculated by using the 3D model of the plating module 400 that is created in the 3D model creator 802. That is, the electric potential estimated value φt can be represented by a formula such as that shown below.

(Formula 4)

In the present case, F is a function representing the 3D model of the plating module 400, and each of ai,t, bi,t, and so on is a Fourier coefficient of the outer-edge-part current density jt(θ) explained above. In this regard, the function F can be determined mathematically, based on the 3D model obtained from the 3D model creator 802. Further, as shown below, the above function F is subjected to Taylor expansion around ai,t=0 and bi,t=0. In this regard, although the following formula is an approximate formula including terms until a first-order term, it is possible to take addition of a term(s) of an order(s) equal to or higher than a second order into consideration.

(Formula 5)

In an embodiment, the observation value calculator 808 calculates, from the outer-edge-part current density jt(θ) at time t, an electric potential estimated value φt at time t by using the following observation equation. In the present case, wt refers to noise.

(Formula 6)

The above observation equation is based on the formula, that has been shown above, of the Taylor expansion of the function F representing the 3D model of the plating module 400. In this regard, an observation equation different from that shown above may be used for obtaining the electric potential estimated value φt.

The Kalman filter 810 is constructed to correct, by using actual measurement result in the plating module 400, the “state” of the plating module 400 estimated by the state estimator 806. Specifically, for correction, the Kalman filter 810 uses an actual measured value of electric potential obtained from the electric potential sensor 470. In an embodiment, based on a difference between a measured value of electric potential obtained from the electric potential sensor 470 and an electric potential estimated value φt calculated by the observation value calculator 808, the Kalman filter 810 corrects the outer-edge-part current density jt(θ) (that is, the Fourier coefficients ai,t and bi,t) estimated by the state estimator 806.

In this regard, since the substrate Wf is rotated by the rotation mechanism 448 as explained above, measured values of electric potential at many measurement points positioned along a circumferential direction of the substrate Wf are obtained. Thus, correction is made based on the measured values at the above plural measurement points, so that more accurate outer-edge-part current density can be obtained.

The outer-edge-part current density jt(θ), that has been estimated and corrected by using the state space model 804 as explained above, is outputted to the current density calculator 812. Based on the outer-edge-part current density obtained from the state space model 804, the current density calculator 812 calculates current density of plating current in a region 64 (refer to FIG. 6) positioned on the inward side of the outer edge part 62 in the substrate Wf. Unlike the outer edge part 62 of the substrate Wf, the region 64 is not grasped by the substrate holder 440 and is exposed to the plating liquid. Current flows into the region 64 from the plating liquid in the plating tank. That is, the current density calculator 812 calculates current density of current that flows into the substrate Wf from the plating liquid in the plating tank via an interface between the plating liquid and the substrate wf. The film thickness of the plated film formed on the substrate Wf is dependent on the above current density. In the following description, the above current density is simply referred to as “plating current density,” and the plating current density in position k on the substrate Wf (the region 64) at time t is described as jk,t.

The plating current density jk,t and the outer-edge-part current density jt(θ) are tied by specific relationship with each other. Specifically, the plating current density is determined based on the outer-edge-part current density and the physical structure of the plating module 400. Thus, similar to the case of the electric potential estimated value φt explained above, the plating current density jk,t can be represented, by using the 3D model of the plating module 400, as the formula shown below.

(Formula 7)

In the present case, Gk is a function representing the 3D model of the plating module 400, and each of ai,t, bi,t, and so on is a Fourier coefficient of the outer-edge-part current density jt(θ). The function Gk can be determined numerically, based on the 3D model of the plating module 400 obtained from the 3D model creator 802. Further, as shown below, the above function Gk is subjected to Taylor expansion around ai,t=0 and bi,t=0. In this regard, although the following formula is an approximate formula including terms until a first-order term, it is possible to take addition of a term(s) of an order(s) equal to or higher than a second order into consideration.

(Formula 8)

In an embodiment, the current density calculator 812 can calculate the plating current density jk,t by using the above formula.

The film thickness calculator 814 is constructed to calculate, based on the plating current density jk,t obtained from the current density calculator 812, the film thickness of the plated film formed on the substrate Wf. In an embodiment, the film thickness calculator 814 calculates, by using the following formula, a deposition rate vk,t and film thickness wk,t with respect to plating in position K on the substrate Wf at time t.

(Formula 9)

In this regard, M and ρ represent molecular weight and density of the plated film extracted on the substrate Wf, respectively, z represents the valence of plating reaction, and F represents the Faraday constant. The film thickness calculator 814 may calculate, by estimating future plating current density and a future deposition rate by using the above-explained state equation, the film thickness wk,t at a point in time when the plating process is completed (time t=T) rather than calculating a film thickness wk,t at present.

The end-point determiner 816 determines, based on the plated film thickness obtained by the film thickness calculator 814, the end point of the plating process with respect to the substrate Wf. For example, the end-point determiner 816 may terminates the plating process when the estimated present film thickness wk,t has reached desired thickness, or may estimate time required to reach the end point of the plating process based on the estimated present film thickness wk,t and the estimated future deposition rate vk,s (S=t, . . . , T).

As explained above, according to the plating apparatus 1000 of the present embodiment, film thickness of a plated film can be estimated based on a measured value from the electric potential sensor 470, by using a state space model. Accordingly, in a plating process, change in film thickness of a plated film formed on the to-be-plated surface Wf-a of the substrate Wf can be grasped in real time.

### Second Embodiment

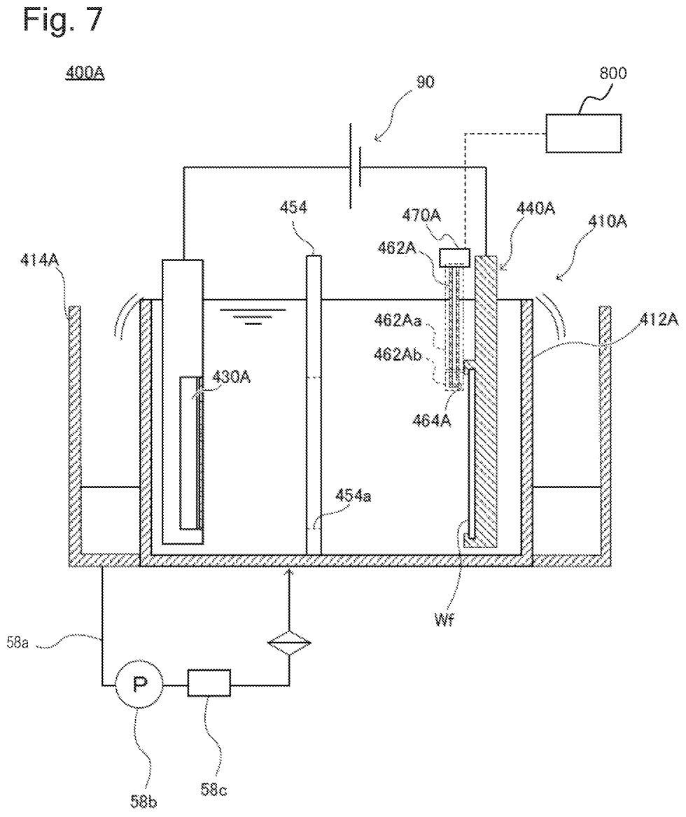

FIG. 7 is a longitudinal section view which schematically shows a construction of a plating module 400A in a different embodiment. In this embodiment, the substrate Wf is arranged vertically. That is, the substrate Wf is held in such a manner that its plate surface is oriented in a horizontal direction. As shown in FIG. 7, the plating module 400A comprises a plating tank 410A which holds plating liquid in the inside thereof, an anode 430A arranged in the inside of the plating tank 410A, and a substrate holder 440A. The substrate Wf may be any one of a rectangular substrate and a circular substrate.

The anode 430A is arranged in such a manner that it faces the plate surface of the substrate Wf in the plating tank. The anode 430A is connected to a positive electrode of an electric power source 90, and the substrate Wf is connected to a negative electrode of the electric power source 90 via a substrate holder 440A. As a result of application of a voltage between the anode 430A and the substrate Wf, current flows in the substrate Wf, and a metal film is formed on the surface of the substrate Wf under existence of plating liquid.

The plating tank 410A comprises an inner tank 412A in which the substrate Wf and the anode 430A are arranged, and an overflow tank 414A adjacent to the inner tank 412A. It is constructed in such a manner that the plating liquid in the inner tank 412A overflows into the overflow tank 414A over a side wall of the inner tank 412A.

One end of a plating liquid circulating line 58a is connected to the bottom of the overflow tank 414A, and the other end of the plating liquid circulating line 58a is connected to the bottom of the inner tank 412A. A circulating pump 58b, a thermostatic unit 58c, and a filter 58d are installed in the plating liquid circulating line 58a. The plating liquid overflows into the overflow tank 414A over the side wall of the inner tank 412A, and, thereafter, is returned to the inner tank 412A from the overflow tank 414A via the plating liquid circulating line 58a. In this manner, the plating liquid circulates between the inner tank 412A and the overflow tank 414A via the plating liquid circulating line 58a.

The plating module 400A further comprises an adjusting board (a regulation plate) 454 for adjusting distribution of electric potential on the substrate Wf. The adjusting board 454 is arranged in a position between the substrate Wf and the anode 430A, and comprises opening 454a for limiting an electric field in the plating liquid.

The plating module 400A is further provided with a pipe 436A in the plating tank 410A. For example, the pipe 462A may be formed by using resign such as PP (polypropylene), PVC (polyvinyl chloride), or the like. Similar to the pipe 462 in the above-explained embodiment, the pipe 462A comprises a first part 462Aa comprising an open end 464A positioned in a region between the substrate Wf and the anode 430A, and a second part 462Ab positioned in the region distant from the region between the substrate Wf and the anode 430A. Further, the second part 462Ab of the pipe 462A is provided with an electric potential sensor 470A. A detection signal from the electric potential sensor 470A is inputted to the control module 800. The control module 800 is the same as that explained with reference to FIG. 5.

Similar to the case of the plating module 400 in the first embodiment, in the plating module 400A in the second embodiment that has been explained above, real-time detection by the electric potential sensor 470A can be performed during the plating process. Further, the control module 800 measures, based on the detected value obtained by the electric potential sensor 470A, film thickness of the plated film. Thus, it becomes possible to measure, in real time during the plating process, change in the film thickness of the plated film formed on the to-be-plated surface of the substrate Wf. Further, similar to the case explained in relation to the first embodiment, the control module 800 may adjust a plating condition(s) based on the film thickness of the plated film.

In the above description, embodiments of the present invention have been explained based on some examples; and, in this regard, the above explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

1000 Plating apparatus
100 Load port
110 Transfer robot
120 Aligner
200 Pre-wet module
300 Pre-soak module
400 Plating module
500 Washing module
600 Spin rinse dryer
700 Transfer device
800 Control module
412 Inner tank
420 Membrane
422 Cathode region
424 Anode region
426 Anode mask
430 Anode
440 Substrate holder
442 Ascending/descending mechanism
448 Rotation mechanism
450 Resistive element
452 Driving mechanism
456 Paddle
462 Pipe
464 Open end
468 Filling mechanism
470 Electric potential sensor
802 3D model creator
804 State space model
806 State estimator
808 Observation value calculator
810 Kalman filter
812 Current density calculator
814 Film thickness calculator
816 End-point determiner
62 Outer edge part
441 Electric contact
90 Electric power source

What is claimed is:

1. A plating apparatus comprising:
a plating tank for storing plating liquid;
a substrate holder for holding a substrate;
an anode arranged in the plating tank in such a manner that it faces the substrate held by the substrate holder;
an electric potential sensor constructed in such a manner that it is arranged in a position close to the substrate held by the substrate holder, and measures electric potential of the plating liquid; and
a state space model constructed to estimate current density of current flowing through an outer edge part of the substrate, based on a measured value of electric potential of the plating liquid obtained by the electric potential sensor and by using a state equation and an observation equation.

2. The plating apparatus according to claim 1, wherein the state equation of the state space model describes time evolution relating to the current density of the current flowing through the outer edge part of the substrate.

3. The plating apparatus according to claim 2, wherein the observation equation of the state space model describes relationship between the current density of the current flowing through the outer edge part of the substrate and potential of the plating liquid in a position of the electric potential sensor.

4. The plating apparatus according to claim 3 comprising
a plating module comprising at least the plating tank, the substrate holder, the anode, and the electric potential sensor; wherein
the relationship between the current density and the potential of the plating liquid is that based on a function representing a 3D model of the plating module.

5. The plating apparatus according to claim 1, wherein the state space model further comprises a Kalman filter constructed to correct, based on the measured value obtained by the electric potential sensor, result of estimation of the current density of the current flowing through the outer edge part of the substrate.

6. The plating apparatus according to claim 1 further comprising a current density calculator constructed to calculate, based on the current density estimated by the state space model, plating current density of plating current flowing into the substrate from the plating liquid.

7. The plating apparatus according to claim 6 further comprising a film thickness calculator constructed to calculate, based on the plating current density calculated by the current density calculator, film thickness of a plated film formed on the substrate.

8. The plating apparatus according to claim 6, wherein the outer edge part of the substrate is a part, which is grasped by the substrate holder, of the substrate.

9. The plating apparatus according to claim 8, wherein the plating current density calculated by the current density calculator is current density in a region positioned on the inward side of the outer edge part in the substrate.
